(19) United States
(12) Patent Application Publication
(10) Pub. No.: US 2011/0260226 A1
(43) Pub. Date: Oct. 27, 2011

(54) SEMICONDUCTOR DEVICE AND METHOD FOR FORMING THE SAME

(75) Inventors: Chang Youn HWANG, Icheon-si (KR); Dong Sauk KIM, Seoul (KR)

(73) Assignee: HYNIX SEMICONDUCTOR INC., Icheon-si (KR)

(21) Appl. No.: 12/978,015

(22) Filed: Dec. 23, 2010

(30) Foreign Application Priority Data
Apr. 26, 2010 (KR) 10-2010-0038526

(51) Int. Cl. H01L 27/108; H01L 21/28

(52) U.S. Cl. 257/296; 438/586; 257/E27.084; 257/E21.19

(57) ABSTRACT

A semiconductor device and a method for forming the same are disclosed. The semiconductor device includes a gate formed over an active region of a semiconductor substrate, a first spacer formed at a sidewall of the gate, a first contact plug formed at a lower sidewall of the first spacer being coupled to the active region, a second spacer formed at a sidewall of the first spacer over the first contact plug, and a second contact plug formed over the first contact plug.

### CROSS-REFERENCE TO RELATED APPLICATION

The present application claims priority to Korean patent application number 10-2010-0038526, filed on 26 Apr. 2010, which is incorporated by reference in its entirety.

### BACKGROUND OF THE INVENTION

Embodiments of the present invention relate to a semiconductor device and a method for forming the same, and more particularly to a semiconductor device for increasing a contact-margin between storage electrode contact plugs and reducing parasitic capacitance, and a method for forming the same.

Recently, most of electronic appliances comprise a semiconductor device. The semiconductor device comprises electronic elements such as a transistor, a resistor and a capacitor. These electronic elements are designed to perform a respective function of each electronic element, and integrated on a semiconductor substrate. For example, electronic elements such as a computer or a digital camera include a memory chip for storing information and a processing chip for controlling information. The memory chip and the processing chip include electronic elements integrated on a semiconductor substrate.

The semiconductor devices have a need for an increase in an integration degree thereof, in order to satisfy consumer demands for superior performances and low prices. Such an increase in the integration degree of a semiconductor device entails a reduction in a design rule. As a memory capacity of a semiconductor device increases and the design rule decreases, a greater number of patterns are formed in a limited cell area, and thus the size of the pattern decreases.

A contact plug of a storage node is used as an electrical passage between a transistor and a storage node (e.g., a capacitor of DRAM). In order to form the contact plug of the storage electrode, a contact hole is formed and a conductive material is buried in the contact hole. With the increasing integration degree of the semiconductor device, the area of the contact hole of the storage node decreases in size, and thus a mask patterning for forming the contact hole may be difficult.

In addition, as the area of the contact plug of the storage node decreases in size, the coupling area between a junction region of the transistor and the storage node decreases in size, i.e., an overlay margin of the storage node decreases, and thus an unexpected defective may occur in the semiconductor device.

In order to secure the overlay margin, a Self-Aligned Contact (SAC) method may be used. The SAC method may form an etch barrier layer of any one of a polysilicon layer, a nitride film and an oxide nitride film, and perform etching using the etch barrier layer, so that a coupling area with the storage node is secured.

However, an etch barrier layer may be lost in the SAC method, so that the etch barrier layer decreases in thickness. In this case, a bit line capacitance (Cb) may increases, and thus characteristics of the semiconductor device may be deteriorated.

In order to reduce the bit line capacitance, the bit line should be reduced in size. However, the loss of the bit line hard mask may be abruptly increased. In addition, the bit line hard mask may be additionally lost or damaged in an etching process for forming a subsequent storage electrode contact plug spacer or in a planarization process for forming a storage electrode contact plug.

In this case, it is impossible for a bit line hard mask to achieve a minimum thickness for preventing a failed SAC contact between the storage electrode and the bit line. If a deposition thickness is increased to guarantee such a minimum thickness of the bit line hard mask, it is difficult to perform gap-filling in a patterning process for forming a bit line and a depositing process of a subsequent interlayer insulating film.

In addition, in order to increase an overlay margin between the storage electrode and the storage electrode contact plug, a new method for forming the storage electrode contact hole by combination of the dry etching and the wet etching has been proposed. However, even in this new method, the loss of spacer occurs at an upper part of the storage electrode contact during the etching process for forming the storage electrode contact plug spacer, so that an interlayer insulating film may be exposed, or a failed SAC between the storage electrode contact plug and the bit line contact may be generated due to the exposed interlayer insulating film.

### BRIEF SUMMARY OF THE INVENTION

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

Various embodiments of the present invention are directed to providing a semiconductor device and a method for forming the same that substantially obviate one or more problems due to limitations and disadvantages of the related art.

An object of the present invention is to provide a semiconductor device and a method for forming the same, which can solve the problems of the related art. According to the related art, if a gate spacer is reduced in thickness to increase an overlay margin between a storage electrode and a storage electrode contact plug in proportion to the increasing integration degree of a semiconductor device, bit line capacitance is increased so that characteristics of the semiconductor device are deteriorated. In accordance with an exemplary embodiment of the present invention, a semiconductor device includes a gate formed over an active region of a semiconductor substrate, a first spacer formed at sidewalls of the gate, a first storage electrode contact plug formed at a lower sidewall of the first spacer being coupled to the active region, a second spacer formed at a sidewall of the first spacer over the first storage electrode contact plug, and a second storage electrode contact plug formed over the first storage electrode contact plug.

The gate may include a laminated structure of a polysilicon layer, a barrier metal layer, a gate conductive layer, and a hard mask layer.

The first storage electrode contact plug may have a smaller thickness than the polysilicon layer.

The first storage electrode contact plug may have a thickness of 200□ to 300□.

In accordance with another exemplary embodiment of the present invention, a method for forming a semiconductor device includes forming a gate over an active region of a semiconductor substrate, forming a first spacer at sidewalls of the gate, forming a first storage electrode contact plug at a lower sidewall of the first spacer, the first storage electrode contact plug being coupled to the active region, forming a second spacer at a sidewall of the first spacer over the first storage electrode contact plug, and forming a second storage electrode contact plug over the first storage electrode contact plug.

The forming of the gate may include forming a polysilicon layer on the semiconductor substrate, forming a barrier metal layer over the polysilicon layer, forming a gate conductive layer over the barrier metal layer, forming a hard mask layer over the gate conductive layer, and patterning the hard mask layer, the gate conductive layer, the barrier metal layer and the polysilicon layer.

The forming of the first storage electrode contact plug may include forming an interlayer insulating film over the first spacer formed at sidewalls of the gate, etching the interlayer insulating film to expose the active region using an exposure mask defining a storage electrode contact hole, and forming the storage electrode contact hole, forming a contact plug by burying the storage electrode contact hole, and partially etching the contact plug.

The contact plug may be formed to have a thickness of 1800□ to 2200□.

The partially etching of the contact plug may use an etching gas, such as CF₄, CHF₃, H₂, O₂, N₂, C₄F₆ or Ar, under pressure of 5 mT to 30 mT and power of 500 Watt to 3000 Watt.

The partially etching of the contact plug may include etching the contact plug to a thickness smaller than that of the polysilicon layer.

The forming of the first storage electrode contact plug may include forming the first storage electrode contact plug to have a thickness of 200□ to 300□.

The forming of the second spacer may include forming a spacer material over the first storage electrode contact plug, and performing an etch-back process on the spacer material.

The spacer material may be formed to have a thickness of 30□ to 100□.

The performing of the etch-back process on the spacer material may include etching back the spacer material using an etching gas includes any one selected from among CF₄, CHF₃, H₂, O₂, N₂, C₄F₆, Ar and a combination thereof under, under pressure of 10 mT to 50 mT and power of 500 Watt to 2000 Watt.

The forming of the second storage electrode contact plug may include forming a storage electrode contact plug material to be coupled to the first storage electrode contact plug, and performing a planarization etching process on the storage electrode contact plug material so that the gate is exposed.

### BRIEF DESCRIPTION OF THE DRAWINGS

FIG. 1 is a cross-sectional view illustrating a semiconductor device according to an exemplary embodiment of the present invention.

FIGS. 2A to 2E are cross-sectional views illustrating a method for forming a semiconductor device according to another exemplary embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

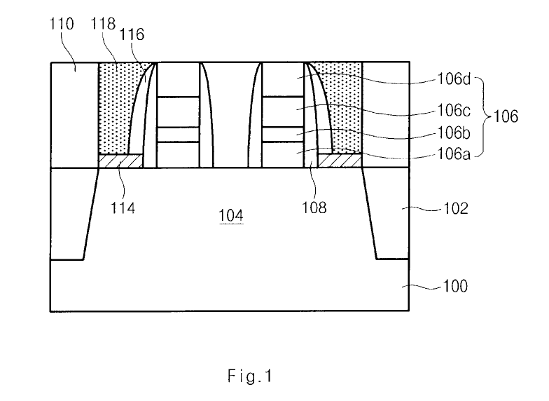

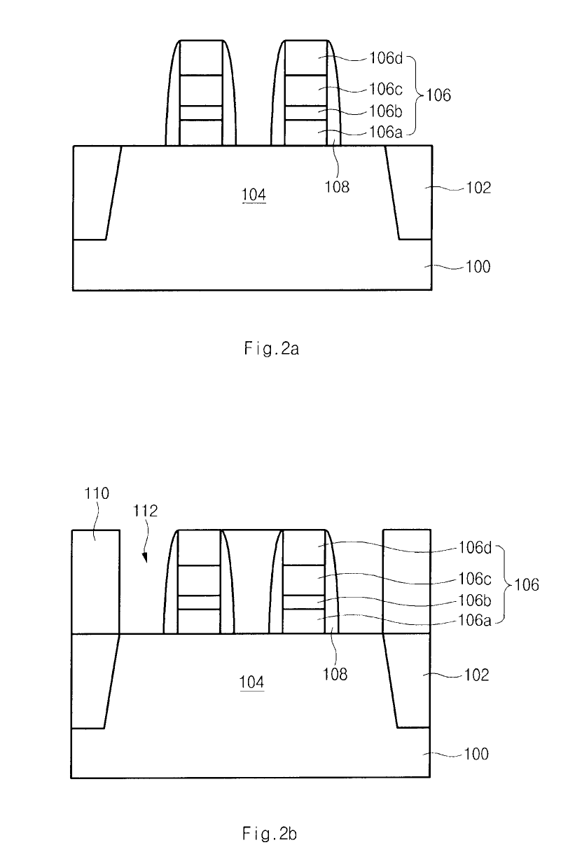

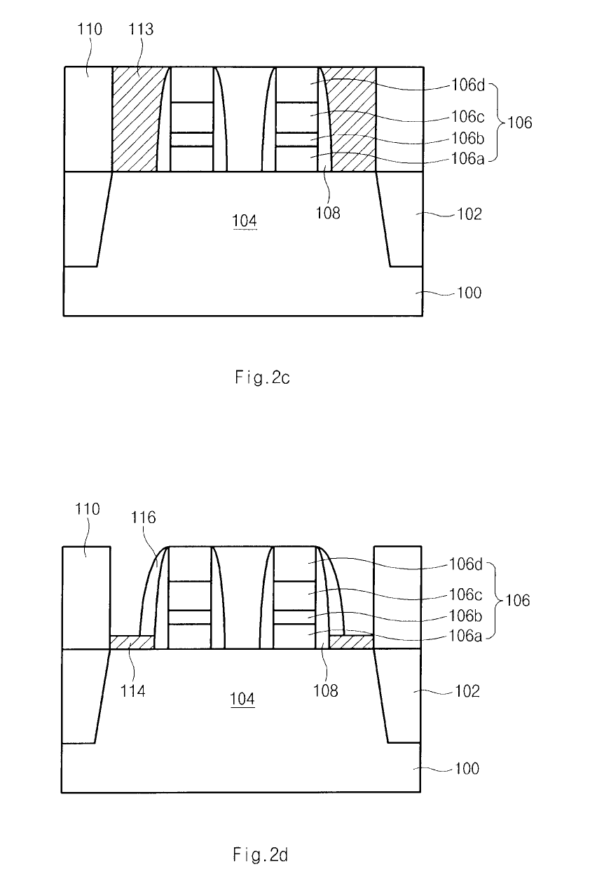

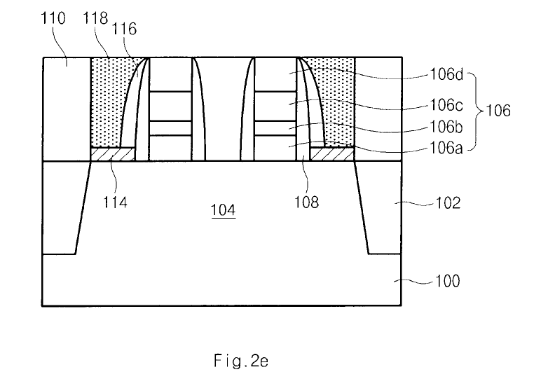

FIG. 1 is a cross-sectional view illustrating a semiconductor device according to an exemplary embodiment of the present invention. FIGS. 2A to 2E are cross-sectional views illustrating a method for forming a semiconductor device according to another exemplary embodiment of the present invention.

Referring to FIG. 1, the semiconductor device according to the exemplary embodiment of the present invention includes a gate 106 in which a laminated structure of a polysilicon layer 106a, a barrier metal layer 106b, a gate conductive layer 106c and a hard mask layer 106d is patterned. In this case, the polysilicon layer 106a is formed over a semiconductor substrate 100 including an active region 104 defined by a device isolation film 102.

The semiconductor device may include a first spacer 108, a first storage electrode contact plug 114, a second spacer 116, and a second storage node contact plug 118. The first spacer 108 is formed at sidewalls of the gate 106. The first storage electrode contact plug 114 is formed at a sidewall of the first spacer 108, is coupled to an active region 104, and has a lower height than the polysilicon layer 106a. The second spacer 116 is formed at a sidewall of the first spacer 108 and is located on the first storage node contact plug 114. The second storage node contact plug 118 is coupled to the first storage node contact plug 114.

As described above, the semiconductor device according to the exemplary embodiment of the present invention may increase an overlay margin between the storage node contact plug and the storage node due to the second spacer that is formed at the sidewall of the first spacer and located over the first storage node contact plug 114. In addition, the semiconductor device may reduce bit line capacitance, so that it may increase semiconductor device characteristics.

A method for forming the above-mentioned semiconductor device according to the exemplary embodiment of the present invention will hereinafter be described with reference to FIGS. 2A to 2E.

Referring to FIG. 2A, a polysilicon layer 106a, a barrier metal layer 106b, a gate conductive layer 106c and a hard mask layer 106d are sequentially formed over the semiconductor substrate 100 including the active region 104 defined by a device isolation film 102, and are patterned so that the gate 106 is formed. Subsequently, the first spacer 108 is formed at a sidewall of the gate 106.

Referring to FIG. 2B, after an interlayer insulating film 110 is formed over the entire surface including the gate 106 in which the first spacer 108 is formed, a photoresist pattern (not shown) is formed by an exposure and development process, for example, using a mask for defining the storage node contact hole. The interlayer insulating film 110 is etched to expose the active region 104 using the photoresist pattern as an etch mask. After that, a process for forming the bit line contact and the bit line may be performed, however a detailed description thereof will herein be omitted for convenience of description.

Referring to FIG. 2C, the material of the storage node contact plug is formed over the entire surface so that the storage node contact hole 112 (See FIG. 2B) is buried with the storage node contact plug material, and a planarization etching process is performed on the storage node contact plug material so that the top of the interlayer insulating film 110 is exposed, resulting in formation of the contact plug 113. In this case, the contact plug 113 has the height of 1800 Å to 2200 Å.

Referring to FIG. 2D, the contact plug 113 is partially etched, so that the first storage node contact plug 114 is formed at the bottom of the storage node contact hole 112 (See FIG. 2B). Here, the first storage node contact plug 114 may have a smaller thickness than the polysilicon layer 106a. The second spacer 116 formed in a subsequent process is formed to cover the barrier metal layer 106b located on the polysilicon layer 106a, resulting in reduced bit line capacitance (Cb). Here, the first storage node contact plug having the above thickness may be formed using an etching gas includes any one selected from among CF₄, CHF₃, H₂, O₂, N₂, C₄F₆, Ar and a combination thereof, under the pressure of 5 mT to 30 mT and the power of 500 Watt to 3000 Watt. In addition, the first storage node contact plug 114 may have a thickness of 200 Å to 300 Å.

Subsequently, a spacer material is deposited over the entire surface including the first storage node contact plug 114. Here, the spacer material may be deposited to have a thickness of 30 Å to 100 Å. Subsequently, the etch-back process is performed on the spacer material, so that the second spacer 116 is formed at the sidewall of the first spacer 108. Here, the second spacer 116 may be formed using the etching gas, such as CF₄, CHF₃, O₂ or Ar, under the pressure of 10 mT to 50 mT and the power of 500 Watt to 2000 Watt.

In this case, the second spacer 116 may increase an overlay margin between the storage node formed in a subsequent process and the storage node contact plug. In addition, the second spacer 116 may reduce bit line capacitance (Cb) along with the first spacer 108 formed at sidewalls of the gate 106.

Referring to FIG. 2E, after a material for the storage node contact plug is deposited over the entire surface including the first storage node contact plug 114, a planarization etching process is performed to expose the interlayer insulating film 110, so that the second storage node contact plug 118 is formed.

As apparent from the above description, according to the embodiment of the present invention, a contact plug is formed and recessed so that a first storage node contact plug is formed to have a smaller thickness than the polysilicon layer of the gate, and a second spacer is formed on the result of the first storage node contact plug. As a result, an overlay margin between the storage node formed in a subsequent process and the storage node contact plug may increase, and bit line capacitance may decrease by the first spacer formed at the sidewall of the gate and the second spacer, resulting in the improvement of semiconductor device characteristics.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a gate formed over an active region of a semiconductor substrate;
a first spacer formed at sidewalls of the gate;
a first storage electrode contact plug formed at a lower sidewall of the first spacer being coupled to the active region;
a second spacer formed at a sidewall of the first spacer over the first storage electrode contact plug; and
a second storage electrode contact plug formed over the first storage electrode contact plug.

2. The semiconductor device according to claim 1, wherein the gate includes a stacked structure of a polysilicon layer, a barrier metal layer, a gate conductive layer, and a hard mask layer.

3. The semiconductor device according to claim 2, wherein the first storage electrode contact plug has a smaller thickness than the polysilicon layer.

4. The semiconductor device according to claim 1, wherein the first storage electrode contact plug has a thickness of 200 Å to 300 Å.

5. A method for forming a semiconductor device comprising:
forming a gate over an active region of a semiconductor substrate;
forming a first spacer at sidewalls of the gate;
forming a first storage electrode contact plug at a lower sidewall of the first spacer being coupled to the active region;
forming a second spacer at a sidewall of the first spacer over the first storage electrode contact plug; and
forming a second contact plug over the first contact plug.

6. The method according to claim 5, wherein the forming of the gate includes:
forming a polysilicon layer on the semiconductor substrate;
forming a barrier metal layer over the polysilicon layer;
forming a gate conductive layer over the barrier metal layer;
forming a hard mask layer over the gate conductive layer; and
patterning the hard mask layer, the gate conductive layer, the barrier metal layer and the polysilicon layer.

7. The method according to claim 5, wherein the forming of the first storage electrode contact plug includes:
forming an interlayer insulating layer over the first spacer formed at a sidewall of the gate;
etching the interlayer insulating film to expose the active region using a mask defining a storage electrode contact hole;
forming a contact plug in the contact hole; and
etching an upper portion of the contact plug.

8. The method according to claim 7, wherein the contact plug is formed to have a thickness of 1800 Å to 2200 Å.

9. The method according to claim 7, wherein the etching of the upper portion of the contact plug is performed using an etching gas includes any one selected from among CF₄, CHF₃, H₂, O₂, N₂, C₄F₆, Ar and a combination thereof, under pressure of 5 mT to 30 mT and power of 500 Watt to 3000 Watt.

10. The method according to claim 7, wherein the etching of the upper portion of the contact plug includes:
etching the contact plug to a thickness smaller than that of the polysilicon layer.

11. The method according to claim 5, wherein the forming of the first storage electrode contact plug, the first storage electrode contact plug has a thickness of 200 Å to 300 Å.

12. The method according to claim 5, wherein the forming of the second spacer includes:
forming a spacer material over the first storage electrode contact plug; and
performing an etch-back process on the spacer material.

13. The method according to claim 12, wherein the spacer material is formed to have a thickness of 30 Å to 100 Å.

14. The method according to claim 12, wherein the etch-back process on the spacer material is performed using an etching gas includes any one selected from among CF₄, CHF₃, H₂, O₂, N₂, C₄F₆, Ar and a combination thereof, under pressure of 10 mT to 50 mT and power of 500 Watt to 2000 Watt.

15. The method according to claim 5, wherein the forming of the second storage electrode contact plug includes:
forming a storage electrode contact plug material to be coupled to the first storage electrode contact plug; and
performing a planarization etching process on the storage electrode contact plug material so that the gate is exposed.
